(19) United States
(12) Patent Application Publication
(10) Pub. No.: US 2018/0065845 A1
(43) Pub. Date: Mar. 8, 2018

(54) MANUFACTURING METHOD FOR A MICROMECHANICAL DEVICE INCLUDING AN INCLINED OPTICAL WINDOW AND CORRESPONDING MICROMECHANICAL DEVICE

(71) Applicant: Robert Bosch GmbH, Stuttgart (DE)

(72) Inventors: Benjamin Steuer, Waldenbuch (DE); Stefan Pinter, Reutlingen (DE)

(21) Appl. No.: 15/694,589

(22) Filed: Sep. 1, 2017

(30) Foreign Application Priority Data
Sep. 7, 2016 (DE) 102016216918.1

(51) Int. Cl. B81C 1/00; B81B 7/00; G02B 27/00

(52) U.S. Cl. CPC B81C 1/00626; B81B 7/0058; G02B 26/0833; B81C 2201/0116; B81B 2201/042; G02B 27/0006

(57) ABSTRACT

A manufacturing method for a micromechanical device including an inclined optical window and a corresponding micromechanical device. The method includes: providing a first substrate having front and back sides and a recess; applying a second substrate on the front side, the second substrate being thermally deformable and having a first through hole above the recess which has a smaller lateral extension than the recess; forming a flap area on the second substrate above/below the first through hole which is situated in a first position with respect to the first substrate; thermally deforming the second substrate, the flap area being moved into a second position within the recess which is inclined with respect to the first position and optionally subsided into the recess; removing the flap area from the second substrate; and attaching the optical window on the second substrate above/below the first through hole in the second inclined position.

### RELATED APPLICATION INFORMATION

The present application claims priority to and the benefit of German patent application no. 10 2016 216 918.1, which was filed in Germany on Sep. 7, 2016, the disclosure of which is incorporated herein by reference.

### FIELD OF THE INVENTION

The present invention relates to a manufacturing method for a micromechanical device including an inclined optical window and a corresponding micromechanical device.

### BACKGROUND INFORMATION

Although it is also possible to use arbitrary optical devices and systems, the present invention and the underlying object are explained based on optical micromechanical micromirror scanning devices.

Micromechanical MEMS components must be protected against harmful external environmental influences (e.g., wet, aggressive media, etc.) for their protection. It is also necessary to protect the components against mechanical contact/destruction as well as to allow them to be separated from a wafer composite into chips by sawing. In many cases, it must also be made possible to set a specific atmosphere (e.g., type of gas and/or gas pressure) by a hermetic encapsulation.

The encapsulation of MEMS components with the aid of a cap wafer, which includes cavities and through holes, in the wafer composite has been extensively established. For this purpose, a cap wafer is aligned to the wafer including the MEMS structures and the two wafers are joined together. The joining may take place, for example, via anodic bonding or direct bonding (connection between glass and silicon without a bonding agent), via eutectic joining layers or via glass solders or glues. The MEMS component(s) is/are located below the cavities of the cap wafer, electrical bond pads being accessible via the through holes in the cap wafer for connecting the MEMS component(s) using thin wires.

The previously described protection and, additionally, a transparent window having a high optical quality and, possibly, also having special optical coatings are necessary for optical micromechanical MEMS components (MOEMS), such as for micromirrors. In some cases, through holes for the electrical connection are implemented in the caps.

Reflections are formed on the boundary surfaces when optical beams pass through the transparent window. When the stationary reflections of a micromechanical micromirror scanning device are located in the scanning area of the micromirror, their intensity exceeds that of the projected image and is perceived as interference. An anti-reflection coating of the optical window merely reduces the intensity of these interfering reflections. Since the micromirror usually oscillates symmetrically in its resting position or is deflected, the reflection always remains in the scanning area when the optical window is in parallel to the resting position of the reflecting surface and when the distance between the reflecting plane and the optical window is small (this is always the case in MEMS components).

The only possibility of avoiding interference due to the reflections is to guide them out of the scanning area in that the optical window and the reflecting surface are not parallel to one another in the non-deflected state. There are two options to achieve this, namely, on the one hand, by an inclination of the optical window or, on the other hand, by an inclination of the resting position of the mirror. Both options are known in the related art.

Inclined windows for separated chips are, for example, provided in EP 1 688 776 A1. Inclined windows or also other types of windows with which reflections are avoidable are described for the wafer level packaging in EP 1 748 029 A2.

According to EP 1 748 029 A2, three-dimensional surface structures (for example inclined windows) are manufactured from a transparent material (glass or plastic) in a wafer composite. The methods by which the three-dimensional structures are manufactured are either very expensive or do not yield the necessary optical quality. Wafers including the corresponding three-dimensional structures are moreover problematic when it comes to processing, for example during wafer bonding, since the structures may be easily damaged.

Further methods for manufacturing protective caps including inclined optical windows are, for example, discussed in DE 10 2008 040 528 A1, DE 10 2010 062 118 A1, and DE 10 2012 206 858 A1.

### SUMMARY OF THE INVENTION

The present invention provides to a manufacturing method for a micromechanical device including an inclined optical window as described herein as well as a corresponding micromechanical device as described herein.

Refinements are the subject matter of the further particular descriptions herein.

The idea underlying the present invention is to manufacture the inclined position of the optical window by thermally deforming a substrate layer.

The present invention thus enables a cost-effective manufacturing method for a micromechanical device including an inclined optical window which may be used, for example, as a protective wafer for a micromechanical micromirror scanning device. The inclined transparent optical windows are manufacturable with high optical quality. The manufacturing method according to the present invention is robust and suitable for series production.

The inclined optical windows may be manufactured using processes which are customary in the MEMS and semiconductor technologies. Scratches, particles, and damage to the inclined optical widow are easily preventable during processing.

According to one refinement, the recess is configured as a second through hole. This allows for the recess to be easily manufactured.

According to another refinement, the second through hole has a stepped and/or beveled wall profile which forms a stop for the flap area in the second inclined position during the thermal deformation of the second substrate. In this way, it is possible to precisely define the inclination of the optical window.

According to another refinement, the recess is formed as a first cavity which extends starting from the front side toward a first diaphragm area on the back side of the first substrate, the first diaphragm area forming a stop for the flap area in the second inclined position and the first diaphragm area being removed after the thermal deformation of the second substrate so that a second through hole is formed from the first cavity. A stop may thus be defined via the first diaphragm area.

According to another refinement, the recess is formed as a second cavity which extends starting from the back side toward a second diaphragm area on the front side of the first substrate, the flap area being formed by structuring the second diaphragm area. This makes it possible for the third wafer substrate to be dispensed with.

According to another refinement, the first substrate and the second substrate are wafer substrates which are bonded on top of one another after the recess has been formed in the first substrate and the first through hole has been formed in the second substrate. This makes large-volume batch processing possible.

According to another refinement, the flap area is structured from a third substrate after the third substrate has been bonded on the second substrate. This makes it possible to manufacture the flap area easily and precisely.

According to another refinement, a vacuum is applied to the back side or an overpressure is applied to the front side during thermal deformation. This supports the thermal deformation step.

According to another refinement, a vacuum, which supports the thermal deformation, is enclosed in the first cavity. This serves to internally support the thermal deformation. If this is not sufficient, an overpressure may additionally also be applied to the front side.

According to another refinement, the second substrate is a glass substrate. Such a glass substrate is easily controllable during thermal deformation.

Additional features and advantages of the present invention are elucidated in the following based on specific embodiments with reference to the drawings.

Identical reference numerals in the figures denote identical elements or elements having an identical function.

### BRIEF DESCRIPTION OF THE DRAWINGS

FIGS. 1a through 1f show schematic cross-sectional illustrations for elucidating a manufacturing method for a micromechanical device including an inclined optical window and a corresponding micromechanical device according to a first specific embodiment of the present invention.

FIGS. 2a through 2e show schematic cross-sectional illustrations for elucidating variations of a manufacturing method for a first substrate of a micromechanical device including an inclined optical window according to the first specific embodiment of the present invention.

FIGS. 3a through 3e show schematic cross-sectional illustrations for elucidating a manufacturing method for a micromechanical device including an inclined optical window and a corresponding micromechanical device according to a second specific embodiment of the present invention.

FIGS. 4a through 4e show schematic cross-sectional illustrations for elucidating a manufacturing method for a micromechanical device including an inclined optical window and a corresponding micromechanical device according to a third specific embodiment of the present invention.

### DETAILED DESCRIPTION

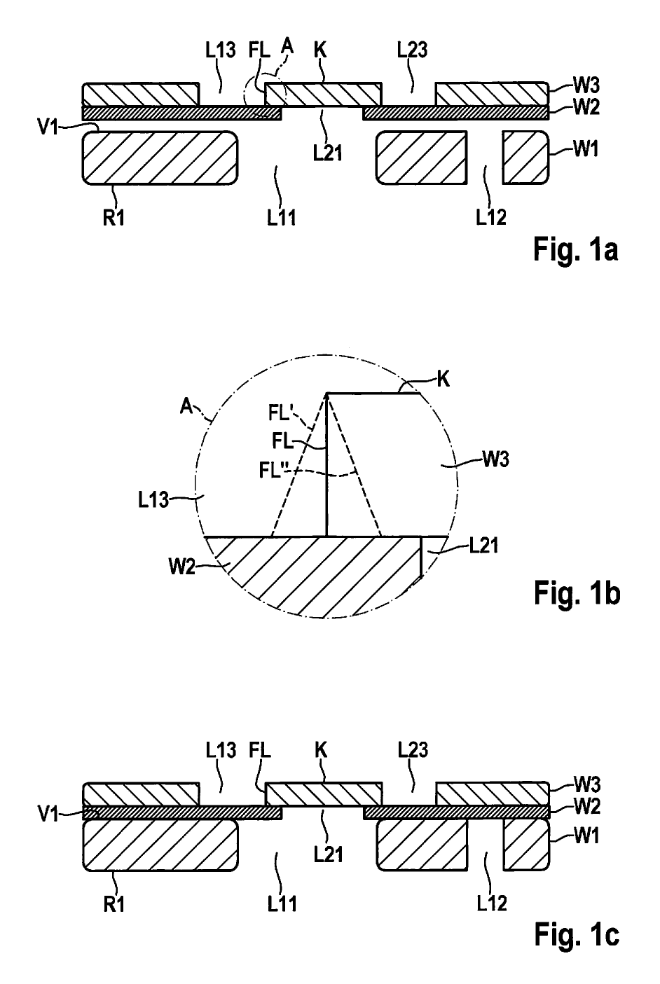

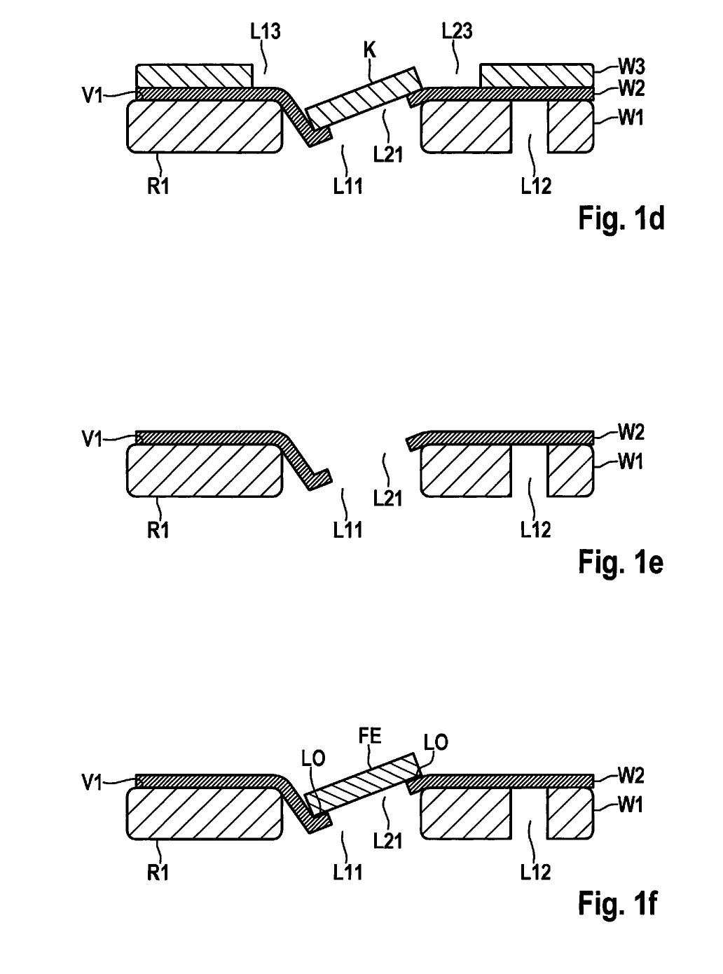

FIGS. 1a through 1f are schematic cross-sectional illustrations for elucidating a manufacturing method for a micromechanical device including an inclined optical window and a corresponding micromechanical device according to a first specific embodiment of the present invention.

The micromechanical device including the inclined optical window according to the first specific embodiment is usable, for example, as a protective wafer device for a micromechanical micromirror scanning device.

The manufacture of the micromechanical device is described on the wafer level, although it is not limited thereto and could also take place on the component level. For simplifying the illustration, only the manufacture of a single inclined optical window is shown, although a plurality of inclined optical windows could be produced on the wafer level.

In FIG. 1a, reference numeral W1 indicates a first wafer substrate, for example a silicon wafer substrate, W2 indicates a second wafer substrate, for example a thermally deformable glass wafer substrate or a plastic substrate, and W3 indicates a third wafer substrate, for example also a silicon wafer substrate.

In a first manufacturing step, the processing of first wafer substrate W1 takes place which has a front side V1 and a back side R1.

Through holes L11 and L12, through hole L12 being optional, are introduced into first wafer substrate W1, for example by KOH etching or sandblasting or with the aid of another arbitrary material removal method (also mechanical drilling, grinding, eroding, or laser processing).

In the same method step, unilateral recesses (not shown) may also be introduced on front side V1 (for example cavities or alignment marks, etc.). Through hole L11 is provided for subsequently accommodating the inclined optical window which forms an optical access to the micromirror (not illustrated). Its edge functions as a hinge and enables a certain subsidence of the optical window into the through hole.

Optional through hole L12 may, for example, accommodate a non-inclined optical window or electrical contacts for contacting via bond lands. The geometry of through holes L11, L12 may be suitably selected or varied.

In a second manufacturing step, second wafer substrate W2, which is a glass wafer substrate in the present example, is processed. Second wafer substrate W2 is structured in such a way that it has a through hole L21 which is subsequently located above through hole L11, thereby defining the location at which the optical window will be placed in a later process step. Through hole L21 has a smaller lateral extension than through hole L11.

Thereafter, structured second wafer substrate W2 is bonded to third wafer substrate W3, for example by anodic bonding or by silicon-glass direct bonding. Subsequently, front side V1 of first wafer substrate W1 is bonded to the opposite side of second wafer substrate W2. This results in the process state according to FIG. 1a.

Second wafer substrate W2 may be alternatively structured in the form of a two-wafer stack including wafer substrates W2 and W3 or also in the form of a three-wafer stack including wafer substrates W1, W2, W3. If wafer substrate is structured in the form of a two-wafer stack W2, W3, the glass of the second wafer substrate may be removed from the areas of the subsequent sawing paths. This is advantageous for the separation process, since in this case only silicon may be sawed at high speed and low cost.

Third wafer substrate W3 is thinned on the other side by grinding and/or polishing and subsequently structured. The trench profile for a suitable edge geometry for the optical window, which is to be inserted subsequently, may be suitably selected, i.e. a straight edge FL or an oblique edge FL' or FL″ may be selected, as shown in FIG. 1b). In other respects, this also applies to the other edges.

Third wafer substrate W3 may alternatively also be structured on its back side prior to the thinning and prior to the bonding of first wafer to wafer substrate W2 or also on its front side following bonding of the first wafer to wafer substrate W2 in the two-wafer stack. In any case, the bonding should take place prior to the thinning.

In particular, a flap area K is formed in third wafer substrate W3 above through hole L21, flap area K being initially positioned in parallel to front side V1, i.e. it is not inclined. Flap area K defines the area in which the optical window will be inserted at a later point in time. The structuring may, for example, take place with the aid of a DRIE etching process.

The surface of flap area K may be smaller than the surface of through hole L11 in first wafer substrate W1 and larger than through hole L21 in second wafer substrate W2. The overlapping area between flap area K and through hole L11 in first wafer substrate W1 forms the sealing and contact surface of the subsequent optical window. The surfaces of flap area K are used to reinforce the sealing and contact surface during the subsequent thermal deformation. They ensure that the sealing and contact surface of the subsequent optical window may have an inclination with respect to front side V1, but that it retains its levelness and smoothness.

Subsequently, second and third wafer substrates W2, W3 are bonded on first wafer substrate W1. This results in the process state according to FIG. 1c).

The three-wafer stack including wafer substrates W1, W2, and W3, which are bonded one on top of the other, is subsequently chucked planarly from back side R1 of first wafer substrate W1 using a chucking device (chuck) and brought to a suitably high temperature which allows the glass of second wafer substrate W2 to be plastically deformed. Due to the vacuum occurring as a result of the chucking through hole L11 of first wafer substrate W1, which is closed off on front side V1 by second wafer substrate W2 and flap area K, the glass is deep-drawn, as shown in FIG. 1d), in the area above through hole L11 which is located next to flap area K. Optionally, overpressure may also be applied from front side V1.

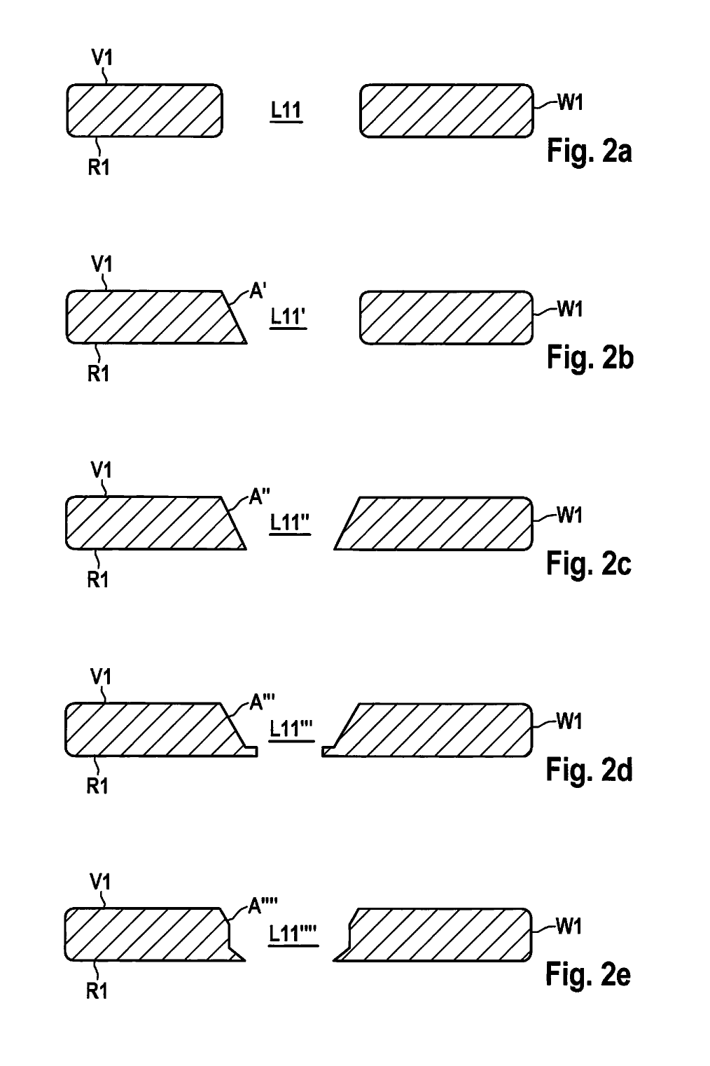

The desired final inclination of flap area K and of the glass area of second wafer substrate W2 stabilized by it may be defined by the process duration or in that a suitable spacer geometry is provided in through hole L11, such as the one illustrated with reference to FIGS. 2a through 2e. According to FIGS. 2b) through 2e, stepped and/or beveled wall profiles A′, A″, A′″, A″″ are provided which form a stop for the flap area in the inclined final position during the thermal deformation of the glass of second wafer substrate W2. These geometries favor the glass forming process. A spacer system of this type may also be completely dispensed with under certain circumstances, as shown in FIGS. 1a and 2a.

Following the thermal deformation, third wafer substrate W3 is removed according to FIG. 1e with the aid of KOH etching, for example. This etching should not be used to etch an optionally provided spacer system at through hole L11 (cf. FIGS. 2b) through 2e at all or only to a minimal extent. In order to minimize the etching time for first wafer substrate W1, holes or slits may be introduced on the exposed surface of the third wafer substrate. These structures increase the etching surface and enable a lateral etching attack on other crystal planes which are etched faster. The shapes and dimensions of the holes or slits are to be suitably configured for maximizing the etching speed. The introduction of structures of this type for supporting the etching process may, for example, take place in one process step together with the formation of flap area K. Finally, according to FIG. 1e, only deformed second wafer substrate W2 having through hole L12 remains on first wafer substrate W1, through hole L21 of second wafer substrate W2 defining the position of the inclined optical window which is now to be attached. Geometrically, inclined means that the normal of the optical window is tilted or inclined with respect to the normal of front side V1.

Optical window FE may be manufactured from glass of high optical quality having a suitable thermal expansion coefficient. The starting material is, for example, a glass wafer of a suitable thickness and optical quality. On one side of optical window FE, a sealing and adhesive medium is, for example, circumferentially applied on the wafer plane, for example glass solder is applied using screen printing and cured (sintered).

Optical windows FE are, for example, subsequently separated and attached on a tape, the separation being effected, for example, by standard glass sawing or laser processing, or sandblasting, etc.

Optical window FE having glass solder LO may then be introduced into the window seat of oblique through hole L21 with the aid of an assembly system. The method used for this purpose and the corresponding devices are known from the SMD (surface-mount device technology. The joining of optical window FE with second wafer substrate W2 takes place in the periphery of through hole L21 during a hot process.

The wafer composite of wafer substrates W1, W2, which is equipped with optical window FE, is planarly chucked from the side of first wafer substrate W1 and brought to a suitably high temperature at which glass solder LO melts. This temperature should be below the softening temperature of the window glass.

Due to the pressure difference, glass solder LO is squeezed on the sealing surface and bonds optical window FE to second wafer substrate W2 in the periphery of through hole L21. After the cooling, the micromechanical device including the inclined, hermetically sealed optical window FE is complete and may be used for further processing, for example for being connected to a micromirror scanning device, as shown in FIG. 1f.

Although optical window FE protrudes at front side V1 according to FIG. 1f, the process may be controlled in such a way that optical window FE subsides into through hole L11 in such a way that it is slanted on the one hand, and no longer protrudes at the front side on the other hand, which is advantageous for many applications.

This type of further processing of the micromechanical device including the inclined optical window may take place with bonding methods which are conventionally used in micromechanics (bonding using glass solder or a glue, eutectic bonding, anodic bonding, etc.) for creating a hermetically sealed joint with MEMS or MOEMS wafers.

One particular advantage is that the inclined surface of optical window FE in first wafer substrate W1 is essentially or completely subsided into through hole L11 and thus protected. Optical window FE therefore cannot be damaged during further processing, i.e. scratches, marks, and adhering particles may be essentially prevented. This is true in particular for glass solder wafer bonding, in which the micromechanical device including inclined optical window FE is bonded to an MOEMS wafer at high mechanical pressure.

One alternative according to the first specific embodiment (not illustrated) is that optical window FE is placed from back side R1 of first wafer substrate W1 from below on second wafer substrate W2 and bonded thereto.

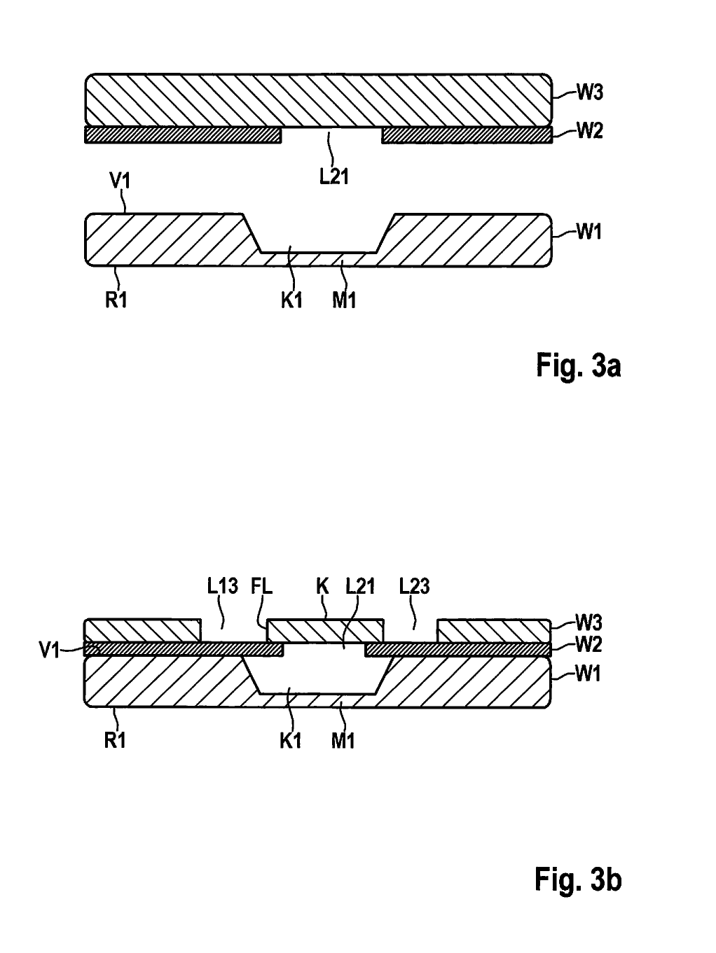

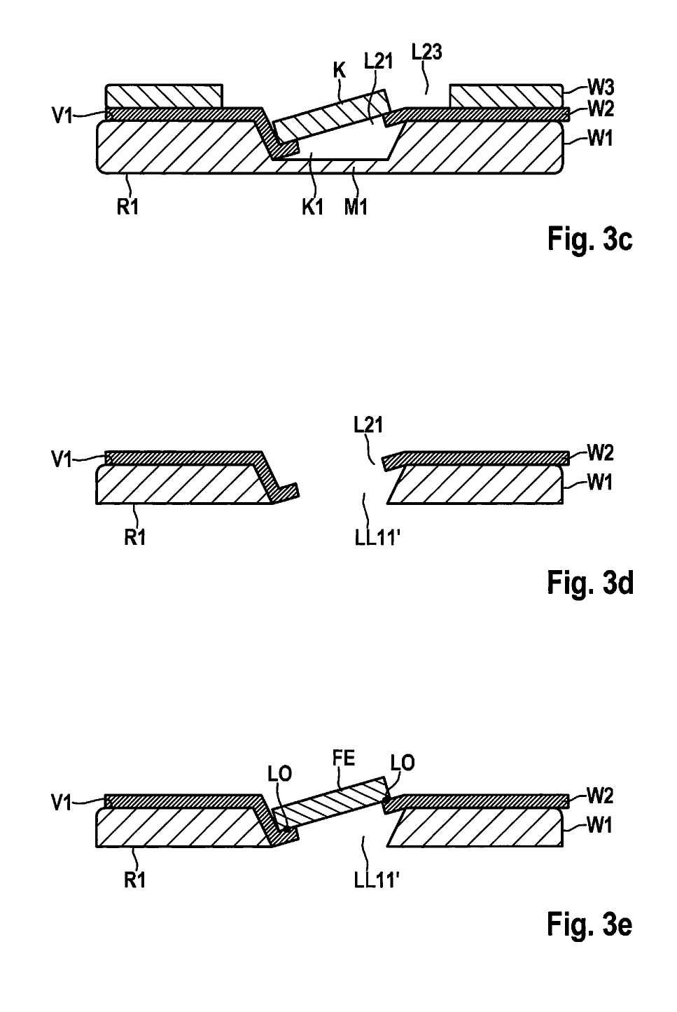

FIGS. 3a through 3e are schematic cross-sectional illustrations for elucidating a manufacturing method for a micromechanical device including an inclined optical window and a corresponding micromechanical device according to a second specific embodiment of the present invention.

In the second specific embodiment, there is no through hole initially formed in first wafer substrate W1 according to FIG. 3a, but there is a first cavity K1 which extends starting from front side V1 toward a diaphragm area M1 on back side R1 of first wafer substrate W1.

Diaphragm area M1 forms a stop for flap area K in the second inclined position. In cavity K1, which is closed off on front side V1 by second wafer substrate W2 and the flap area, a vacuum is enclosed when the three-wafer stack is formed from wafer substrates W1, W2, W3, as shown in FIG. 3b). The local plastic deformation of second wafer substrate W2 in the area of first cavity K1 takes place as a result of this vacuum, without the need to planarly chuck first wafer substrate W1. If the vacuum is not sufficient, an overpressure may be additionally applied to front side V1.

After the thermal deformation, the result of which is shown in FIG. 3c), diaphragm area M1 is removed, so that a through hole LL11′ of first wafer substrate W1 is formed from first cavity K1. At the same time, third wafer substrate W3 is completely removed, which results in the state shown in FIG. 3d). Since it is not possible in this specific embodiment to externally generate the pressure difference during the thermal deformation, the simultaneous processing of a plurality of wafers in one furnace is possible for a more cost-effective and simple batch process.

Finally, with reference to FIG. 3e, the optical window is inserted similarly to FIG. 1f and thermally joined with the aid of glass solder to second wafer substrate W2 in the periphery of through hole L21.

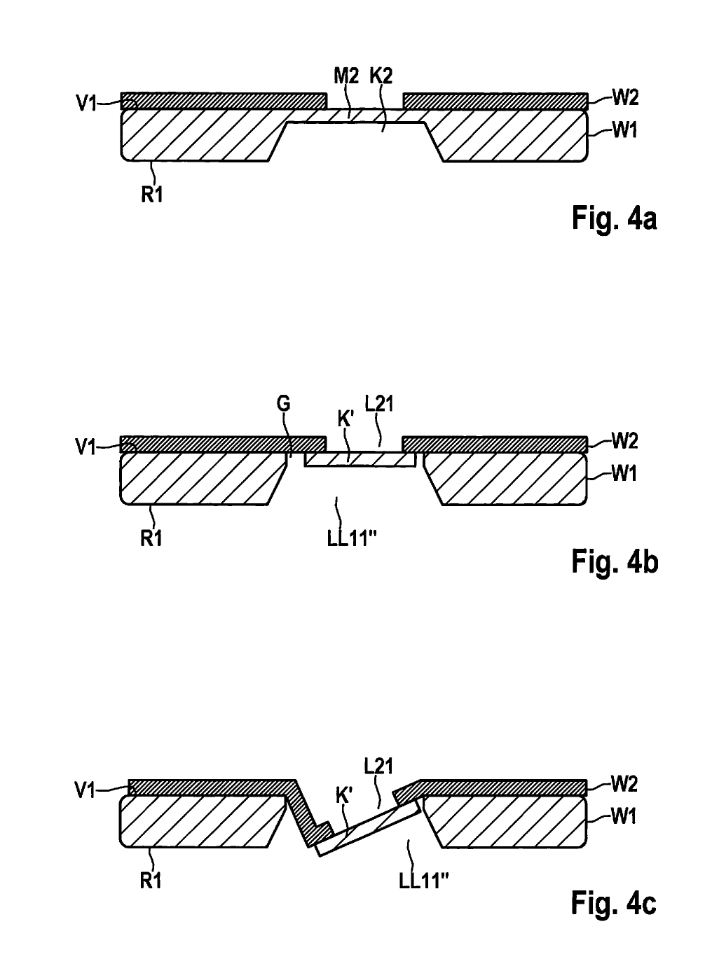

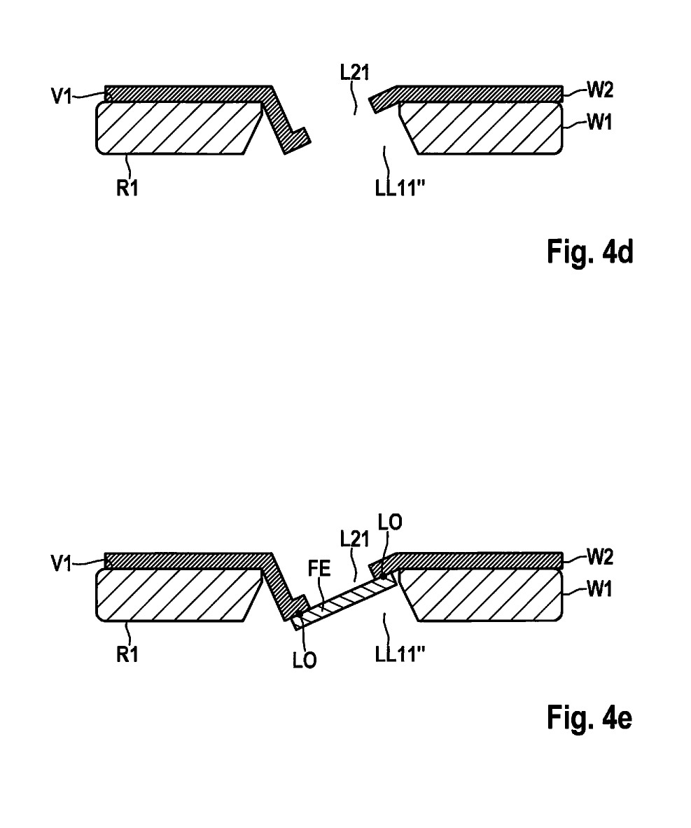

FIG. 4a through 4e are schematic cross-sectional illustrations for elucidating a manufacturing method for a micromechanical device including an inclined optical window and a corresponding micromechanical device according to a third specific embodiment of the present invention.

In the third specific embodiment, no through hole is initially formed either in first wafer substrate W1 according to FIG. 4a, but a cavity K2 which extends starting from back side R1 toward a diaphragm area M2 on front side V1 of first wafer substrate W1.

Furthermore, in the third specific embodiment, third wafer substrate W3 is completely dispensed with. In this specific embodiment, flap area K′ is formed by structuring diaphragm area M2, which takes place by a back-side etching of first wafer substrate W1. This is illustrated in FIG. 4b).

The subsequent thermal melting and slanting of flap area K′ takes place the same way as in the first and the second specific embodiment described above, as shown in FIG. 4c).

According to FIG. 4d), flap area K′ is subsequently removed by etching, thus forming a through hole LL11″ in first wafer substrate W1.

Also similarly to the first and the second specific embodiment, optical window FE is attached, which is however inserted from back side R1 in this specific embodiment.

Since in this specific embodiment flap area K′ is provided on the bottom side of second wafer substrate W2 in through hole LL11″, a melting of the glass of second wafer substrate W2 is advantageously prevented with the chucking device (chuck) as compared to the first specific embodiment.

Although the present invention has been described with reference to the exemplary embodiments, it is not limited thereto. The above-named materials and topologies are in particular only exemplary and not limited to the elucidated examples.

In particular, other inclination directions, angles, geometries, etc., may be selected.

What is claimed is:

1. A manufacturing method for a micromechanical device including an inclined optical window, the method comprising:
providing a first substrate having a front side and a back side and a recess;
applying a second substrate on the front side, the second substrate being thermally deformable and having a first through hole above the recess which has a smaller lateral extension than the recess;
forming a flap area on the second substrate above or below the first through hole which is situated in a first position with regard to the first substrate;
thermally deforming the second substrate, the flap area being moved into a second position within the recess which is inclined with regard to the first position and optionally subsided into the recess;
removing the flap area from the second substrate; and
attaching the optical window on the second substrate above or below the first through hole in the second inclined position.

2. The manufacturing method of claim 1, wherein the recess is formed as a second through hole.

3. The manufacturing method of claim 2, wherein the second through hole has a stepped and/or beveled wall profile which forms a stop for the flap area in the second inclined position during the thermal deformation of the second substrate.

4. The manufacturing method of claim 1, wherein the recess is formed as a first cavity which extends starting from the front side toward a first diaphragm area on the back side of the first substrate, the first diaphragm area forming a stop for the flap area in the second inclined position and the first diaphragm being removed after the thermal deformation of the second substrate so that a second through hole is formed from the first cavity.

5. The manufacturing method of claim 1, wherein the recess is formed as a second cavity which extends starting from the back side toward a second diaphragm area on the front side of the first substrate, the flap area being formed by structuring the second diaphragm area.

6. The manufacturing method of claim 1, wherein the first substrate and the second substrate are wafer substrates which are bonded on top of one another after the recess has been formed in the first substrate and the first through hole has been formed in the second substrate.

7. The manufacturing method of claim 1, wherein the flap area is structured from a third substrate after the third substrate has been bonded on the second substrate.

8. The manufacturing method of claim 1, wherein a vacuum is applied to the back side or an overpressure is applied to the front side during thermal deformation.

9. The manufacturing method of claim 4, wherein a vacuum, which supports the thermal deformation, is enclosed in the first cavity.

10. The manufacturing method of claim 1, wherein the second substrate is a glass substrate.

11. A micromechanical device including an inclined optical window, comprising:
a first substrate which has a front side and a back side and a through hole; and
a second substrate which is applied on the front side of the first substrate, the second substrate being deformed in the area of the through hole and having a further through hole which has a smaller lateral extension than the through hole;
wherein the optical window is attached on the second substrate above or below the further through hole in the inclined position.

12. The micromechanical device of claim 11, wherein the first substrate and the second substrate are wafer substrates which are bonded on top of one another.

13. The micromechanical device of claim 11, wherein the second substrate is a glass substrate.

14. The micromechanical device of claim 11, wherein the optical window is attached on the second substrate with the glass solder.

15. The micromechanical device of claim 11, wherein the optical window is essentially subsided into the through hole of the second substrate.
